(19) United States
(12) Patent Application Publication
(10) Pub. No.: US 2009/0293934 A1
(43) Pub. Date: Dec. 3, 2009

(54) Photoelectric Conversion Device

(75) Inventors: Kenichi Okada, Shiga (JP); Takeshi Kyouda, Shiga (JP); Kouichi Hayashi, Shiga (JP); Kenji Tomita, Shiga (JP); Hisao Arimune, Shiga (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/092,704

(22) PCT Filed: Nov. 8, 2006
(86) PCT No.: PCT/JP2006/322299

§ 371 Date: Jul. 7, 2009

(30) Foreign Application Priority Data
Nov. 10, 2005 (JP) 2005-325878
Aug. 30, 2006 (JP) 2006-233302

(51) Int. Cl. H01L 31/00; H02N 6/00

(52) U.S. Cl. 136/246; 136/255

(57) ABSTRACT

A photoelectric conversion device in which a plurality of crystal semiconductor particles 2 of a first conductivity type having a surface layer thereof a semiconductor part 4 of a second conductivity type are bonded at spaced intervals on a surface of a conductive substrate 1, an insulating layer 3 is formed on the conductive substrate 1 extending between the semiconductor particles 2 and 2, a light-transmitting conducting layer 5 is formed on the insulating layer 3 and the crystal semiconductor particles 2, and a collector electrode 7 is formed on a surface of the light-transmitting conducting layer 5. The collector electrode 7 is comprised of a conductor plate with a plurality of through-holes 40 to admit external light into the crystal semiconductor particles 2. The light-transmitting light collection layer 8 is disposed on the light-transmitting conducting layer 5 and the collector electrode 7. Simple manufacturing steps eliminate shadow loss while suppressing resistance loss, thereby providing the high-efficiency photoelectric conversion device.

### TECHNICAL FIELD

The present invention relates to a photoelectric conversion device used in photovoltaics and, in particular, the electrode structure and the light collection structure in a photoelectric conversion device using crystal semiconductor particles.

### BACKGROUND ART

In general photoelectric conversion devices of crystal plate type, a pn junction is formed by forming an n-type semiconductor region on one main surface of a p-type silicon substrate, and a transparent electrode is formed by a light-transmitting conducting layer over the entire main surface, and electrodes are formed on the transparent electrode on the main surface of the substrate and on the back of the substrate, respectively. As an electrode on the transparent electrode, finger electrodes for current collection and a bus bar electrode made of metal are usually employed for improving current collection efficiency. Specifically, the finger electrodes are formed in parallel lines in order to minimize the obstruction to the incidence of light into the pn junction. The bus bar electrode is electrically connected to the finger electrodes and collects the currents from the respective finger electrodes. The finger electrodes usually used are formed by screen printing a thermosetting conductive paste containing silver (Ag) as a conductive material, in parallel lines on the transparent electrode.

Also in the photoelectric conversion device in which crystal semiconductor particles are used to form the pn junction, finger electrodes are formed by screen printing a thermosetting type conductive paste in parallel lines on crystal semiconductor particles or between crystal semiconductor particles or on the side surfaces of crystal semiconductor particle.

In the photoelectric conversion devices of crystal plate type having the finger electrodes and the bus bar electrode, these electrodes are disposed on the light receiving surface, and the problem called shadow loss has occurred. That is, the incident light is blocked by these electrodes on the light receiving surface, causing dead space due to shadow.

The reason why the general photoelectric conversion devices of crystal plate type have the abovementioned electrode structure is to reduce Joule's heat loss in the transparent electrode. That is, in a photoelectric conversion device having no serially connected electrode structure, the carriers generated at the pn junction travel over a long distance to a lead wire output port disposed at the end of the photoelectric conversion device, throughout the transparent electrode and the electrode on the back. As the electrode on the back, a metal electrode is generally used. In this case, the metal electrode has a small resistance, and it is therefore possible to ignore the Joule's heat loss due to the current passing through the metal electrode.

However, the sheet resistance of a thin film composed of the material of the transparent electrode is relatively large, normally 5 to 30Ω/□, so that the power loss due to Joule's heat occurs in the transparent electrode. It is therefore necessary to minimize the power loss due to the Joule's heat by disposing the finger electrodes and the bus bar electrode on the light receiving surface. Consequently, the array of the finger electrodes and the bus bar electrode is designed to minimize the shadow loss and the power loss due to Joule's heat.

A similar problem also occurs in photoelectric conversion devices using spherical crystal semiconductor particles, and the following methods have been proposed to reduce the Joule's heat generated in electrodes. For example, Patent Document No. 1 discloses the mesh method of arranging granulated Si on meshes which are disposed on a substrate knitted in a mesh and are composed of a positive conductor and a negative conductor. Patent Document No. 2 discloses the aluminum method in which crystal semiconductor particles are connected to each other by using aluminum foil. For the purpose of minimizing the shadow loss due to the finger electrodes, Patent Document No. 3 discloses the method of disposing finger electrodes 7′ between crystal semiconductor particles by wire bonding process or printing process, as shown in FIG. 11.

On the other hand, in photoelectric conversion devices as conventional light collection type solar cells, Patent Document No. 4 proposes one in which small-area photoelectric conversion elements obtained by cutting a plate-shaped body of crystal semiconductor composed of crystal silicon are arranged at spaced intervals, and condenser lenses are disposed on the photoelectric conversion elements, respectively.

The photoelectric conversion device using spherical crystal semiconductor particles is disclosed in Patent Document No. 5. This device is obtained by forming apertures in a first aluminum foil; inserting, as crystal semiconductor particles, silicon balls having the n-type outer shell on the p-type central core into the apertures; removing the n-type outer shell on the back of the silicon balls; forming an insulating layer on the surface of the first aluminum foil and on the surfaces of the silicon balls from which the n-type outer shell has been removed; removing the insulating layer at the top portions on the back of the silicon balls; and bonding the silicon balls and a second aluminum foil with a metal bonding portion in between. Spherical lenses for collecting light into the silicon balls are formed on the silicon balls, respectively. In this case, space may occur between the silicon balls, causing a photoelectric conversion loss. Therefore, the spherical lenses are formed on the silicon balls in parallel to their curved surfaces so that the optical energy entered into the space between the silicon balls can be admitted into the silicon balls adjacent to the space.

On the other hand, Patent Document No. 6 proposes the configuration in which the substrate formed in the shape of a concave mirror is used to cause light to be reflected and collected into silicon balls.

### Patent Document No. 1: Japanese Unexamined Patent Publication No. 9-162434

### Patent Document No. 2: Japanese Unexamined Patent Publication No. 6-13633

### Patent Document No. 3: Japanese Unexamined Patent Publication No. 2005-38990

### Patent Document No. 4: Japanese Unexamined Patent Publication No. 8-330619

Patent Document No. 5: U.S. Pat. No. 5,419,782

### Patent Document No. 6: Japanese Unexamined Patent Publication No. 2002-164554

### DISCLOSURE OF THE INVENTION

### Problems to be Solved by the Invention

However, in the mesh method described in Patent Document No. 1, the manufacturing of the mesh-shaped substrate is costly and the uniformity of mesh size is a problem. On the other hand, the aluminum method has the problem that the step of burying the Si particles in predetermined holes is complicated and hence unsuitable for high-speed mass production manufacturing. As a solution to these problems, Patent Document No. 3 proposes to dispose the light receiving surface electrode at the optically inactive portions of the crystal semiconductor particles. However, the width and the thickness of the light receiving surface electrode are limited, and the reduction of resistance loss has a limit. Additionally, as shown in FIGS. 12(a) and 12(b), the connection between the photoelectric conversion devices is made by connecting the bus bar electrodes 9 to the ends of conductive string materials 10 as being linear member or band-shaped member Consequently, the bonding area being in connection is narrow and the bonding strength is insufficient.

In the photoelectric conversion device described in Patent Document No. 4, it is necessary to prepare the small-area photoelectric conversion elements by cutting the plate-shaped crystal semiconductor composed of crystal silicon or the like, and connect the photoelectric conversion elements to each other by tabs or the like. This increases the number of manufacturing steps, resulting in a complicated manufacturing.

In the photoelectric conversion device described in Patent Document No. 5, though the spherical lenses formed in parallel to the curved surfaces of the crystal semiconductor particles are used, if an attempt is made to reduce the light incident angle dependence of photoelectric conversion efficiency by using these spherical lenses, the distance between the crystal semiconductor particles can be increased only to approximately 1/10 of the diameter of the crystal semiconductor particle. This makes it difficult to reduce the amount of semiconductors used in the photoelectric conversion device, which is a disadvantage to lightweight and low-cost.

In the photoelectric conversion device described in Patent Document No. 6, the substrate is deformed in the concave mirror shape, making it difficult to retain the substrate shape. Since the boundary portions of the concave mirror cannot be formed at an acute angle in the manufacturing thereof, the light reflection at the boundary portions cannot be disregarded, causing a photoelectric conversion loss.

It is desirable to provide a lightweight and low-cost photoelectric conversion device by reducing the amount of semiconductors used. Specifically, the minimization of power loss and a reduction of semiconductor element material are attainable by disposing plane electrodes between semiconductor elements functioning as photoelectric conversion elements so that the shadow loss due to a light receiving surface electrode can be minimized and the complexity of steps can be eliminated. The photoelectric conversion element can be manufactured simply without such complicated manufacturing steps as to cut the plate-shaped body of crystal semiconductor. Even if the distance between crystal semiconductor particles is increased to not less than 1/10 of the diameter of the crystal semiconductor particle, the light incident angle dependence of photoelectric conversion efficiency can be lowered, and light reflection structure can be formed without bending the substrate.

### Means for Solving the Problems

In the photoelectric conversion device according to one embodiment of the present invention, a plurality of semiconductor elements functioning as a photoelectric conversion element are disposed at spaced intervals on a surface of a conductive substrate. A light-transmitting conducting layer is formed on the plurality of the semiconductor elements and on the conductive substrate therebetween. A collector electrode is formed on a surface of the light-transmitting conducting layer. The collector electrode is constructed of a conductor plate covering the area between the semiconductor elements and having a plurality of through-holes to admit external light into the semiconductor elements, respectively.

Preferably, the semiconductor elements are crystal semiconductor particles of a first conductivity type having on a surface layer thereof a semiconductor part of a second conductivity type, and a plurality of the crystal semiconductor particles are bonded at spaced intervals onto the conductive substrate. An insulating layer is formed on the conductive substrate extending between the crystal semiconductor particles, and the light-transmitting conducting layer is formed on the insulating layer and on the crystal semiconductor particles. A light-transmitting light collection layer for collecting light into each of the crystal semiconductor particles is formed on the light-transmitting conducting layer and a collector electrode.

The light-transmitting light collection layer preferably collects the light into each of the crystal semiconductor particles by light refraction action. In particular, the light-transmitting light collection layer is formed in a convex curved surface shape above each of the crystal semiconductor particles.

Preferably, the conductive substrate is composed of aluminum, the semiconductor elements are composed of silicon, and the collector electrode contains at least one selected from the group consisting of gold, platinum, silver, copper, aluminum, tin, iron, nickel, chrome and zinc.

Alternatively, instead of the light-transmitting light collection layer, a light reflecting member having a light reflecting surface of a concave mirror shape for collecting light into each of the crystal semiconductor particles may be formed on the collector electrode. Preferably, the light reflecting member has at a lower end of the light reflecting surface an aperture for exposing an upper part of each of the crystal semiconductor particles.

Preferably, the light reflecting member is composed of resin and has on a surface thereof a light reflecting layer composed of metal. The light reflecting layer is preferably composed of aluminum.

More preferably, a light-transmitting light collection layer for collecting light into each of the crystal semiconductor particles is formed on the light-transmitting conducting layer, and a light reflecting member having a light reflecting surface of a concave mirror shape for collecting light into each of the crystal semiconductor particles is formed on the collector electrode.

In the photoelectric conversion device according to other embodiment of the present invention, a plurality of semiconductor elements functioning as a photoelectric conversion element are disposed at spaced intervals on a surface of a conductive substrate. A light-transmitting conducting layer is formed on the plurality of the semiconductor elements and on the conductive substrate therebetween. A collector electrode is formed on a surface of the light-transmitting conducting layer. The collector electrode is constructed of a conductor plate covering the region between the semiconductor elements and having a plurality of through-holes corresponding to the semiconductor elements, respectively.

In the complex type photoelectric conversion device according to other embodiment of the present invention, a plurality of the photoelectric conversion devices are electrically connected to each other with the conductor plate (the collector electrode) in between. Preferably, one edge of the conductor plate of one of the photoelectric conversion devices extends to the adjacent photoelectric conversion device so as to be electrically connected to each other.

### EFFECT OF THE INVENTION

The photoelectric conversion device of the invention has, on the light-transmitting conducting layer, the collector electrode composed of the planar conductor plate in which the plurality of through-holes enabling the semiconductor elements to sufficiently receive light are formed between the semiconductor elements functioning as photoelectric conversion elements. Thus, the respective semiconductor elements can be exposed from the plurality of through-holes admitting external light, thereby minimizing the shadow loss due to the light receiving surface electrode (the collector electrode). Additionally, since the collector electrode is the conductor plate, the complicated step of disposing finger electrodes can be eliminated, and the resistance of the collector electrode (the conductor plate) can be reduced than that of the finger electrodes, thereby minimizing power loss. These permit a reduction in the semiconductor element materials.

The light-transmitting light collection layer can collect the light into the crystal semiconductor particles while avoiding the optically inactive region between the crystal semiconductor particles (the semiconductor elements). Therefore, the light entering into the collector electrode as the planar electrode disposed between the crystal semiconductor particles can also be effectively received by the crystal semiconductor particles, thereby increasing the optically generated current value.

By disposing, on the collector electrode (the conductor plate), the light reflecting member having the light reflecting surface of the concave mirror shape for collecting light into the crystal semiconductor particles, even if the crystal semiconductor particles account for a small area on the conductive substrate, the light can be collected efficiently into the crystal semiconductor particles. Hence, the amount of semiconductors used can be reduced while maintaining high photoelectric conversion efficiency. This enables manufacturing of the lightweight and low-cost photoelectric conversion device.

The light reflecting member of the concave mirror structure is used to collect light, eliminating the need to deform the conductive substrate and the collector electrode. As a result, there is no possibility of damaging the insulating layer. Further, even if the distance between the crystal semiconductor particles is increased to not less than 1/10 of the diameter of the crystal semiconductor particle, the light incident angle dependence of photoelectric conversion efficiency can be lowered.

By disposing the light reflecting member on the collector electrode (the conductor plate) and the light-transmitting light collection layer on the crystal semiconductor particles, light collection efficiency can be improved, and the amount of semiconductors used can be reduced while maintaining high photoelectric conversion efficiency. This enables manufacturing of the lightweight and low-cost photoelectric conversion device.

In the photoelectric conversion device of the invention, the collector electrode is constructed of the conductor plate covering the region between the semiconductor elements and having the through-holes corresponding to the semiconductor elements, respectively. This minimizes the shadow loss due to the collector electrode, and eliminates the complicated step of disposing the finger electrodes. This also reduces the resistance of the collector electrode, thereby minimizing power loss. These permit a reduction in the semiconductor element materials.

In the complex type photoelectric conversion device of the present invention, the photoelectric conversion devices are electrically connected to each other by the conductor plate (the collector electrode), and planar strings are performable, thereby improving tensile strength and ensuring high reliability.

### BRIEF DESCRIPTION OF THE DRAWINGS

FIGS. 1(a) and 1(b) are a plan view showing an example of a first preferred embodiment of the photoelectric conversion device of the invention, and an enlarged sectional view of a key part thereof, respectively;

FIG. 2 is an enlarged sectional view showing a key part in an example of a second preferred embodiment of the photoelectric conversion of the invention;

FIGS. 3(a) and 3(b) are a plan view and a longitudinal sectional view showing the case of having string portions for connecting a plurality of photoelectric conversion devices of the invention, respectively;

FIG. 4 is a side view showing an example of tensile strength testing method in the invention;

FIG. 5 is a longitudinal sectional view showing the positional relationship between a light-transmitting light collection layer and crystal semiconductor particles in the invention;

FIG. 6 is a sectional view showing an example of a third preferred embodiment of the photoelectric conversion device of the invention;

FIG. 7 is a graph showing the reflectance of an aluminum thin film and that of an aluminum bulk;

FIG. 8 is a plan view showing the example of the third preferred embodiment of the photoelectric conversion device;

FIG. 9 is a sectional view showing an example of the third preferred embodiment of a photoelectric conversion module manufactured by using the photoelectric conversion device of the invention;

FIG. 10 is a sectional view showing an example of a fourth preferred embodiment of the photoelectric conversion device of the invention;

FIG. 11 is a plan view of a conventional photoelectric conversion device; and

FIGS. 12(a) and 12(b) are a plan view and a longitudinal sectional view of a photoelectric conversion device provided with bus bar electrode according to a conventional configuration, respectively.

### PREFERRED EMBODIMENTS FOR CARRYING OUT THE INVENTION

The photoelectric conversion device of the present invention will be described in detail with reference to the accompanying drawings.

### First Preferred Embodiment

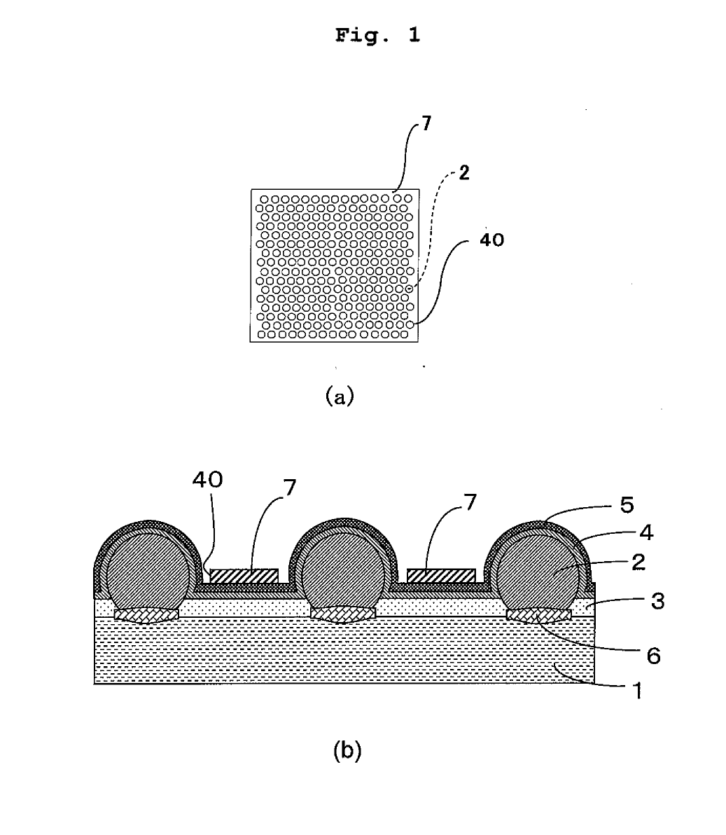

FIGS. 1(a) and 1(b) are a plan view showing an example of a first preferred embodiment of the photoelectric conversion device of the invention, and an enlarged sectional view of a key part thereof, respectively. As shown in FIG. 1(b), in the photoelectric conversion device of the invention, a large number of spherical crystal semiconductor particles 2 of a first conductivity type are disposed at spaced intervals on a conductive substrate 1, and the former and the latter are bonded by means of a welding layer 6 composed of the material of the conductive substrate 1 (for example, aluminum) and the material of the crystal semiconductor particles 2 (for example, silicon). An insulating layer 3 is formed on the conductive substrate 1 extending between the crystal semiconductor particles 2. A semiconductor layer 4 as a semiconductor part of a second conductivity type is formed on the insulating layer 3 and on the crystal semiconductor particles 2. A light-transmitting conducting layer 5 is formed on the surface of the semiconductor layer 4. A conductor plate (a light receiving surface electrode) 7 as a collector electrode having through-holes 40 for admitting light is disposed on the light-transmitting conducting layer 5 extending between the crystal semiconductor particles 2.

The conductive substrate 1 is a plate-shaped body composed of a metal, ceramics with a metal adhered to the surface thereof, or the like. Examples of the metal include aluminum, aluminum alloy, iron, stainless steel and nickel alloy. Examples of the ceramics include alumina ceramics.

A large number of the crystal semiconductor particles 2 of the first conductivity type are bonded onto the surface of the conductive substrate 1, for example, by disposing the particles 2 on the surface of the conductive substrate 1, and heat-treating at a predetermined temperature so that both are welded with the welding layer 6 in between. For example, the crystal semiconductor particles 2 contain, as a microelement, B, Al, Ga or the like when Si is used as the semiconductor and the first conductivity type is of p-type, and contain P, As or the like when the first conductivity type is of n-type.

In the surface of the conductive substrate 1, the insulating layer 3 is interposed between the adjacent crystal semiconductor particles 2 and 2 so as to expose the upper portions of the particles 2. The insulating layer 3 is composed of an insulating material for electrically separating the conductive substrate 1 and the light-transmitting conducting layer 5 corresponding to the positive electrode and the negative electrode, respectively. The insulating material is, for example, a glass composition obtained by compounding filler composed of a glass material for low temperature firing, or an insulating resin composed mainly of silicone resin. The insulating layer 3 can be disposed by forming the abovementioned insulating material in the shape of a layer at the region between the crystal semiconductor particles 2 and 2 throughout the large number of those disposed on the surface of the conductive substrate 1.

The semiconductor layer 4 of the second conductivity type, functioning as the photoelectric conversion element, together with the crystal semiconductor particles 2, is composed of Si or the like and formed as follows. That is, a trace amount of the vapor phase of a phosphorous-based compound for imparting n-type or the vapor phase of boron-based compound for imparting p-type is admitted into the vapor phase of a silane compound by vapor phase growth method, so as to be the semiconductor of a second conductivity type opposite from the first conductivity type of the crystal semiconductor particles 2 (namely, n-type when the first conductivity type is of p-type, and p-type when the first conductivity type is of n-type). The semiconductor layer 4 is formed so as to cover the crystal semiconductor particles 2 and the insulating layer 3. The membranous of the semiconductor layer 4 may be any one of crystalline substance, amorphous substance, and a mixture of crystalline substance and amorphous substance.

As shown in FIG. 1(b), the semiconductor layer 4 is preferably formed along the crystal semiconductor particles 2 and the surface of the insulating layer 3 interposed therebetween, and along the convex curved surface shape of the crystal semiconductor particles 2 whose upper portions are exposed from the insulating layer 3. The formation along the convex curved surface of the crystal semiconductor particles 2 can increase the area of the pn junction between the crystal semiconductor particles 2 of the first conductivity type and the semiconductor layer 4 of the second conductivity type. This enables efficient collection of the carriers generated within the pn junction, providing the photoelectric conversion device functioning as a high-efficiency solar cell.

The light-transmitting conducting layer 5 is laminated on the semiconductor layer 4. As the light-transmitting conducting layer 5, one or more types of oxide based films is selected from SnO₂, In₂O₃, ITO, ZnO and TiO₂, and can be formed by film forming method such as sputtering method or vapor phase growth method, or alternatively by coating and firing method. The effect resulting from an anti-reflection coating can also be expected from the light-transmitting conducting layer 5 by selecting a proper thickness thereof.

In order to reduce the series resistance value of the light receiving surface electrode 7 (the collector electrode) in the photoelectric conversion device, the conductor plate 7 as a planar electrode is disposed which covers the optically inactive part being inactive against the photoelectric conversion between the crystal semiconductor particles 2, and has a plurality of through-holes 40 for admitting light at the locations corresponding to the crystal semiconductor particles 2 being opposed to the light receiving surface electrode 7. The conductor plate 7 is required to be metal having a low electrical resistance, and formed by a conductive material selected from gold, platinum, silver, copper, aluminum, tin, iron, nickel, chrome, zinc, and alloys of these metals such as SUS (stainless steel) and copper-zinc alloy. In other words, the expression of being inactive against photoelectric conversion means having no function of photoelectric conversion.

Thus, by disposing the conductor plate 7, serving as the light receiving surface electrode, on the light-transmitting conducting layer 5 disposed between the crystal semiconductor particles 2 and 2, there is the effect that the conductor plate 7 does not constitute shadow loss.

Further, as shown in FIG. 1(a), the width of the conductor plate 7 can be increased, eliminating the necessity for the bus bar electrode 9 and the finger electrodes 7′, which have been used as the light receiving surface electrodes of the general photoelectric conversion device in the related art. This enables simplification of the manufacturing steps.

### <Method of Manufacturing Photoelectric Conversion Device>

The method of manufacturing the photoelectric conversion device of the present invention will be described sequentially. In the following, aluminum is used as the conductive substrate 1, and silicon is used as the crystal semiconductor particles 2.

Firstly, crystal semiconductor particles 2 of a first conductivity type (for example, p-type) are disposed at spaced intervals on a conductive substrate 1. In the crystal semiconductor particles 2, a trace quantity of an element for example, B, Al or Ga for imparting p-type to Si, or alternatively, P or As for imparting n-type is contained in Si.

The crystal semiconductor particles 2 preferably have a spherical shape, whose convex curved surface can be used to reduce the light incident angle dependence. A large distance between the adjacent crystal semiconductor particles 2 and 2 is preferred for reducing the amount of the crystal semiconductor particles 2 used. Preferably, the distance is larger than the radius of the crystal semiconductor particle 2 (a half of the particle diameter). In this case, the number of the crystal semiconductor particles 2 can be reduced to approximately one-half that when the crystal semiconductor particles 2 are most closely arranged.

Further, the reflectance on the surfaces of the crystal semiconductor particles 2 can be reduced by roughing the surfaces of the crystal semiconductor particles 2. To form the rough surface, the crystal semiconductor particles 2 may be etched in an alkaline solution, or alternatively micro-fabricating process may be performed by a RIE (Reactive Ion Etching) apparatus or the like.

The particle diameter of the crystal semiconductor particles 2 is preferably 0.2 to 0.8 mm. When silicon having a particle diameter exceeding 0.8 mm, the amount of silicon used remains the same as the amount of silicon used, including the portions to be cut, in a photoelectric conversion device of plate-shaped body (bulk) type which is manufactured by cutting a conventional plate-shaped body of crystal silicon (a base plate: wafer). As a result, the use of the crystal semiconductor particles 2 becomes meaningless. On the other hand, below 0.2 mm, it is difficult to assemble the crystal semiconductor particles 2 onto the conductive substrate 1. From the relationship with the amount of silicon used, the particle diameter of the crystal semiconductor particles 2 is more preferably 0.2 to 0.6 mm.

The spherical crystal semiconductor particles 2 can be formed, for example, by melt drop method (jet method) in which silicon melt is solidified and granulated while being dropped.

Next, a large number (several thousands to hundreds of thousands) of crystal semiconductor particles 2 are disposed at spaced intervals on the conductive substrate 1, and heated to not less than the eutectic temperature (577° C.) between the aluminum constituting the conductive substrate 1 and the silicon constituting the crystal semiconductor particles 2, while applying a constant load thereto from above the crystal semiconductor particles 2. Thus, an alloy layer (a welding layer) 6 of the conductive substrate 1 and the crystal semiconductor particles 2 is formed at the bonding portions of the crystal semiconductor particles 2, and the conductive substrate 1 and the crystal semiconductor particles 2 are bonded to each other with the alloy layer 6 in between.

Subsequently, an insulating layer 3 is formed on the conductive substrate 1 extending between the crystal semiconductor particles 2 and 2. The insulating layer 3 is composed of an insulating material for separating the positive electrode and the negative electrode, for example, glass for low temperature firing (so-called glass flit and solder glass) composed of any one of SiO₂, B₂O₃, Al₂O₃, CaO, MgO, P₂O₅, Li₂O, SnO, ZnO, BaO and TiO₂; a glass composition obtained by compounding filler consisting of one or more types of the abovementioned materials; or an organic insulating material such as polyimide resin or silicone resin.

The insulating layer 3 is formed by applying the paste or the solution or the sheet of the above insulating material from above the crystal semiconductor particles 2, or disposing between the crystal semiconductor particles 2, and then heating at a temperature of 577° C. or below, as the eutectic temperature between aluminum and silicon so that the insulating material can be filled in the space between the crystal semiconductor particles 2. This is finally fire solidified or thermally cured. If the heating temperature exceeds 577° C., the alloy layer 6 consisting of aluminum and silicon starts to melt, and the bonding between the conductive substrate 1 and the crystal semiconductor particles 2 becomes unstable. Depending on the case, the crystal semiconductor particles 2 may be separated from the conductive substrate 1, failing to take out the generated current. After forming the insulating layer 3, the surfaces of the crystal semiconductor particles 2 are cleaned by a cleaning solvent containing hydrofluoric acid.

The semiconductor layer 4 is used to form a semiconductor part (the semiconductor layer) 4 on the surface layers of the crystal semiconductor particles 2 and the insulating layer 3 after bonding the crystal semiconductor particles 2 onto the conductive substrate 1, and after forming the insulating layer 3.

For example, the semiconductor layer 4 is composed of Si, and formed on the surface layers of the crystal semiconductor particles 2 and the insulating layer 3 by admitting a trace amount of the vapor phase of a phosphorous-based compound for imparting n-type or the vapor phase of boron-based compound for imparting p-type into the vapor phase of a silane compound by vapor phase growth method or the like. The membranous of the semiconductor layer 4 may be any one of crystalline substances, amorphous substances, and a mixture of a crystalline substance and an amorphous substance. In consideration of light transmittance, a crystalline substance or a mixture of a crystalline substance and an amorphous substance is preferred.

Alternatively, the semiconductor layer 4 may be formed on the surface layer of the crystal semiconductor particles 2 before they are bonded onto the conductive substrate 1, for example, by thermal diffusion method. For example, when the crystal semiconductor particles 2 are of p-type, an n-type layer may be formed on the surface portion in a thickness of 1 μm by inserting the crystal semiconductor particles 2 into a silica tube of 900° C. for 30 minutes, by using phosphorous oxychloride as a dispersing agent. In this case, for electrically separating the semiconductor layer 4 and the alloy layer 6, it is necessary that the surface of the semiconductor layer 4, except for the part of the semiconductor layer 4 which is close to the alloy layer 6, is coated with an acid resistant resist or the like, and the non-coated part is removed by etchant.

The trace element concentration in the semiconductor layer 4 is, for example, approximately 1×10¹⁶ to 1×10²¹ atoms/cm³. Preferably, the semiconductor layer 4 is formed along the convex curved surfaces of the crystal semiconductor particles 2. The formation along the convex curved surfaces of the crystal semiconductor particles 2 can increase the area of the pn junction. This enables efficient collection of the carriers generated inside of the crystal semiconductor particles 2.

Next, a light-transmitting conducting layer 5, which when the conductive substrate 1 is one electrode, also functions as the other electrode, is formed on the semiconductor layer 4. The light-transmitting conducting layer 5 is composed of one or more types of oxide based conducting films selected from SnO₂, In₂O₃, ITO, ZnO and TiO₂, and can be formed by sputtering method, vapor phase growth method, coating and firing method or the like. By selecting the proper thickness, the light-transmitting conducting layer 5 can also offer the effect resulting from an anti-reflection coating.

Since the light-transmitting conducting layer 5 is transparent, there is the effect that, in the region including no crystal semiconductor particle 2, a portion of the incident light can be passed through the light-transmitting conducting layer 5, and reflected from the underlying conductive substrate 1 and then irradiated to the crystal semiconductor particles 2. Consequently, the optical energy irradiated to the entire photoelectric conversion device can be efficiently guided and irradiated to the crystal semiconductor particles 2.

Preferably, the light-transmitting conducting layer 5 is formed along the surface of the semiconductor layer 4 or the surfaces of the crystal semiconductor particles 2, particularly along the convex curved surfaces of the crystal semiconductor particles 2. In this case, the area of the pn junction can be increased, and therefore the light-transmitting conducting layer 5 can efficiently collect the carriers generated inside of the crystal semiconductor particles 2.

Next, for the purpose of reducing the series resistance value between the light-transmitting conducting layer 5 and the external terminal, a conductor plate 7, functioning as a light receiving surface electrode and also a collector electrode, is disposed on the light-transmitting conducting layer 5 extending between the adjacent crystal semiconductor particles 2 and 2, by interposing a conductive bonding member between the conductor plate 7 and the layer 5. This configuration enables the optical current generated by the crystal semiconductor particles 2 to be taken out of the photoelectric conversion device at an extremely low resistance loss.

The conductor plate 7 is composed of a conductor plate with through-holes 40 which cover the space between the crystal semiconductor particles 2 and also correspond to the crystal semiconductor particles 2. The through-holes 40 have a one-to-one correspondence with the crystal semiconductor particles 2, or alternatively, may have a one-to-many correspondence. For example, a plurality of the crystal semiconductor particles 2 may exist inside of a single through-hole 40. Preferably, the conductor plate 7 is a metal plate in which the through-holes 40 are formed at the locations corresponding to the crystal semiconductor particles 2, respectively. The metal plate is preferably made of Al, Cu, Ni, Cr or Ag, or alternatively any alloy composed of a plurality of types of these metals. The thickness of the conductor plate 7 is not less than 5 μm, preferably 10 to 200 μm, and more preferably 20 to 200 μm. When the thickness of the conductor plate 7 is below 5 μm, such a thin conductor plate is liable to increase resistance and difficult to handle. When the thickness of the conductor plate 7 is above 200 μm, the thickness of the conductor plate 7 is relatively large with respect to the crystal semiconductor particles 2 having a diameter of approximately 300 μm. This case is susceptible to the problem that the conductor plate 7 constitutes an obstruction of light collection into the crystal semiconductor particles 2.

### Second Preferred Embodiment

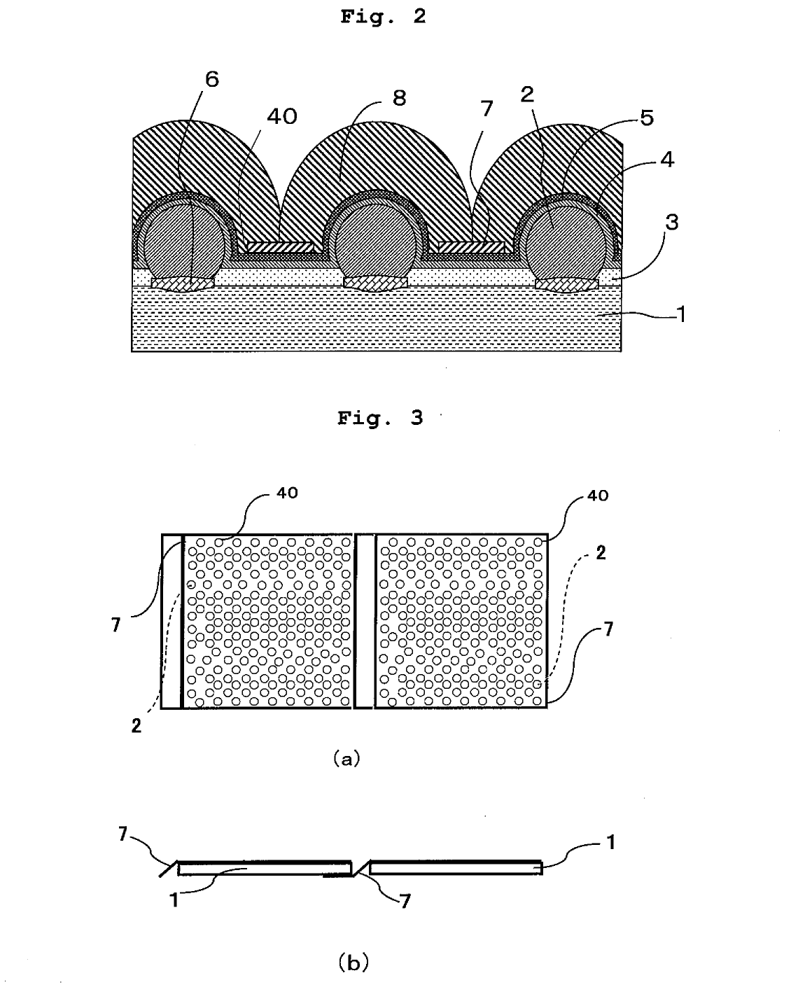

In the photoelectric conversion device of the first preferred embodiment, for example, as shown in FIG. 2, a light-transmitting light collection layer 8 composed of a lens-shaped member is disposed above crystal semiconductor particles 2 in order to effectively admit light into the crystal semiconductor particles 2, while avoiding a conductor plate 7 disposed at the optically inactive region.

The light-transmitting light collection layer 8 is in a non-spherical shape having an upward-convex curved surface for the purpose of efficiently admitting light beams of any incident angles into the crystal semiconductor particles 2. The light-transmitting light collection layer 8 overlies a light-transmitting conducting layer 5 extending over the respective crystal semiconductor particles 2, and the convex portions of the layer 8 have, in a longitudinal section thereof, a contour shape of a substantially semicircular shape having a larger diameter than the crystal semiconductor particles 2, and having a lateral radius smaller than the height thereof.

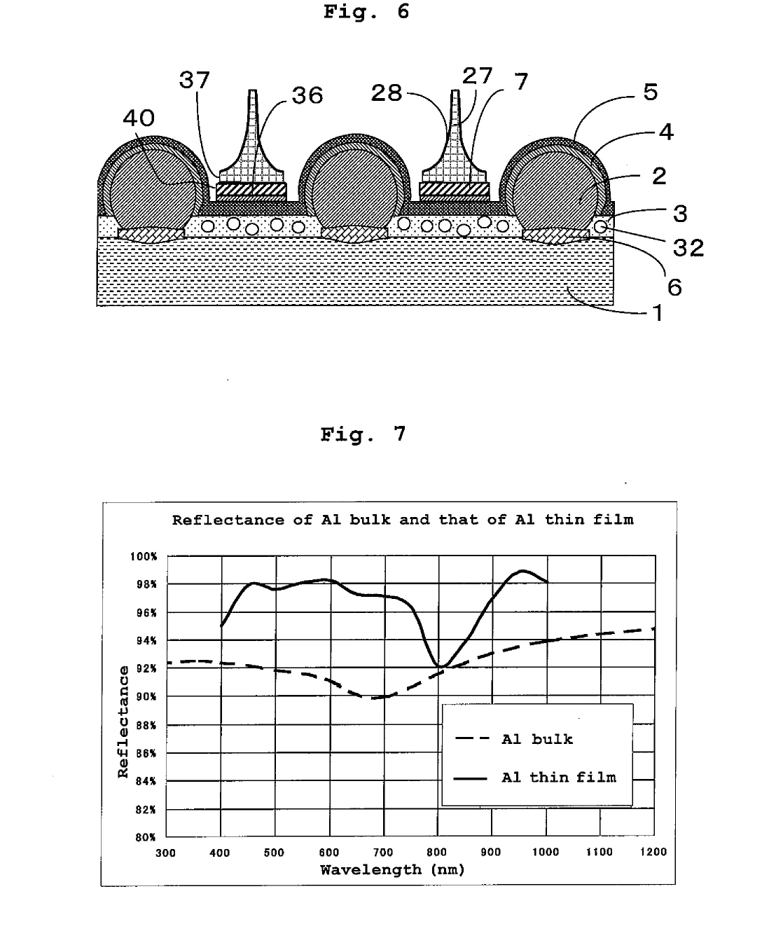

Specifically, the shape of the light-transmitting light collection layer 8 is a non-spherical shape as shown in FIG. 5. Preferably, the apex of the convex portion is in a spherical shape having the same curvature as the crystal semiconductor particles 2, and both sides other than the apex of the contour shape in the longitudinal section of the convex portion are constructed of a circular arc 13 having a larger diameter than the crystal semiconductor particles 2. The convex portion is a body of rotation having a non-spherical shape (a vertically positioned rugby ball-shape) where a perpendicular (a vertical line) passing through the center of the convex portion is the axis of rotation V.

That is, in the longitudinal section of the abovementioned convex portion, both sides other than the apex are in the form of the circular arc 13 having a larger curvature than the crystal semiconductor particle 2. The two circular arcs 13 have a larger curvature than a circle 14 of the crystal semiconductor particle 2 which is parallel to the main surface of the conductive substrate 1 and has the center on a horizontal line H passing through the center of the crystal semiconductor particle 2. The apex of the convex portion has the center on the axis of rotation V, and its longitudinal sectional form corresponds to a circular arc 12 of a circle having substantially the same diameter as the diameter of the crystal semiconductor particle 2. Therefore, the convex portion has, in the longitudinal section thereof, the shape where the circular arc of the apex and the circular arcs on the both sides are connected to each other.

As shown in FIG. 5, the circular arcs 13 and 13 on the both sides in the longitudinal section of the convex portion correspond to a part of the two circles having the same diameter on the right and left sides, respectively, and the diameter of these two circles (indicated by C in FIG. 5) is about 2 to 2.5 times greater than the diameter of the circle of the crystal semiconductor particle 2.

The light collection properties of the convex portions of the light-transmitting light collection layer 8 having a contour shape 11 in the longitudinal section shown in FIG. 5 can be obtained by a computer simulation based on a known analyzing method such as non-sequential light tracking and analyzing method according to Monte Carlo method.

The light transmittance of the light-transmitting light collection layer 8 is preferably 85% or above. In view of workability and transmittance, the thickness thereof is preferably 100 μm to 1 mm, more preferably 200 to 600 μm. Preferably, the light-transmitting light collection layer 8 has at least such a size as to cover all of the crystal semiconductor particles 2 bonded onto the conductive substrate 1.

By disposing the light-transmitting light collection layer 8, the refraction of light can be used to admit light so as to be received while avoiding the optically inactive region extending between the crystal semiconductor particles 2. As a result, shadow loss can be reduced, and the light can be effectively collected into the crystal semiconductor particles 2. This permits an improvement of photoelectric conversion efficiency as a photoelectric conversion device.

The lens-shaped member in the light-transmitting light collection layer 8 may have any shape other than the abovementioned body of rotation, as long as it has a convex curved surface of substantially hemispherical shape. Alternatively, the light-transmitting light collection layer 8 may be formed by laminating a plurality of layers. In this case, the layer adjacent to the plane of incidence and the layer adjacent to the crystal semiconductor particles 2 may have different refractive indexes. Additionally an anti-reflection coating may be formed on the plane of incident.

In the method of forming the light-transmitting light collection layer 8, compression forming, injection molding or the like is used to form a condensing lens-shaped resin sheet in advance. Thereafter, the obtained resin sheet and a photoelectric conversion element made up of the conductive substrate 1 and the crystal semiconductor particles 2 are heat-compressed and integrated at the same time. In this method, adhesive such as an EVA sheet is preferably interposed for adhering the photoelectric conversion element and the condensing lens-shaped resin sheet.

Preferably, the light-transmitting light collection layer 8 is composed of a transparent weather-resistant resin. As the weather-resistant resin, it is possible to use a synthetic resin containing at least one selected from ethylene vinyl acetate resin, fluororesin, polyester resin, polypropylene resin, polyimide resin, polycarbonate resin, polyarylate resin, polyphenylene ether resin, silicone resin, polyphenylene sulfide resin and polyolefin resin. It is particularly desirable to use silicone resin, polycarbonate resin or polyimide resin, which are generally used from the viewpoints of weather resistance, adhesive properties, moisture permeability, chemical resistance and operability.

In accordance with the photoelectric conversion device of the second preferred embodiment, the conductor plate 7 functioning as the collector electrode (the light receiving surface electrode) is disposed on the part of the light-transmitting conductive layer 5 which extends between the crystal semiconductor particles 2, and the light-transmitting light collection layer 8 is disposed so that the refraction of light can be used to admit light so as to be received while avoiding the optically inactive region extending between the crystal semiconductor particles 2 (the optically inactive portion). With this configuration, the light entering into the plane of incidence is not directed to the conductor plate 7 but reaches the crystal semiconductor particles 2. Consequently, there is the effect that the conductor plate 7 of the present invention does not constitute shadow loss.

Further, the conductor plate 7 can use the refraction of light so that the light can be passed and received while avoiding the optically inactive portion if the distance between the crystal semiconductor particles 2 and 2 accounts for substantially a half length of the diameter of the crystal semiconductor particle 2. This permits a large width of the conductor plate 7, contributing to a reduction of resistance loss.

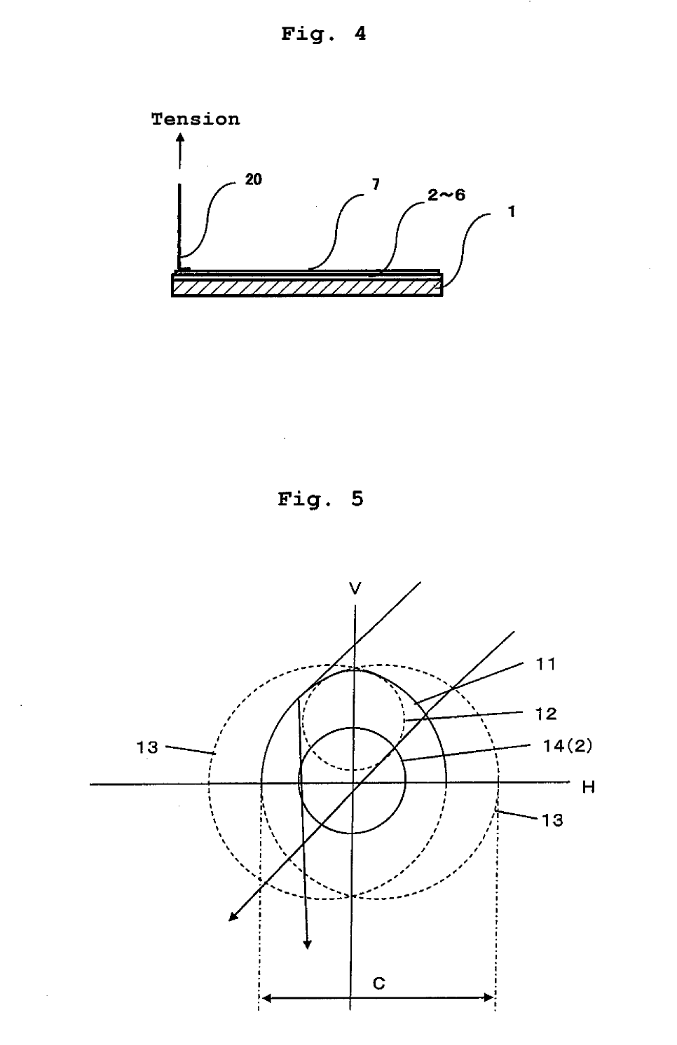

FIGS. 3(a) and 3(b) show an example of complexing where the photoelectric conversion devices of the invention are bonded to each other. In this example, the part of the conductor plate 7 which juts out of the conductive substrate 1 becomes a connecting part to mutually connect the photoelectric conversion devices manufactured by the present invention. For purposes of convenience, the light-transmitting light collection layer 8 is not shown in FIGS. 3(a) and 3(b).

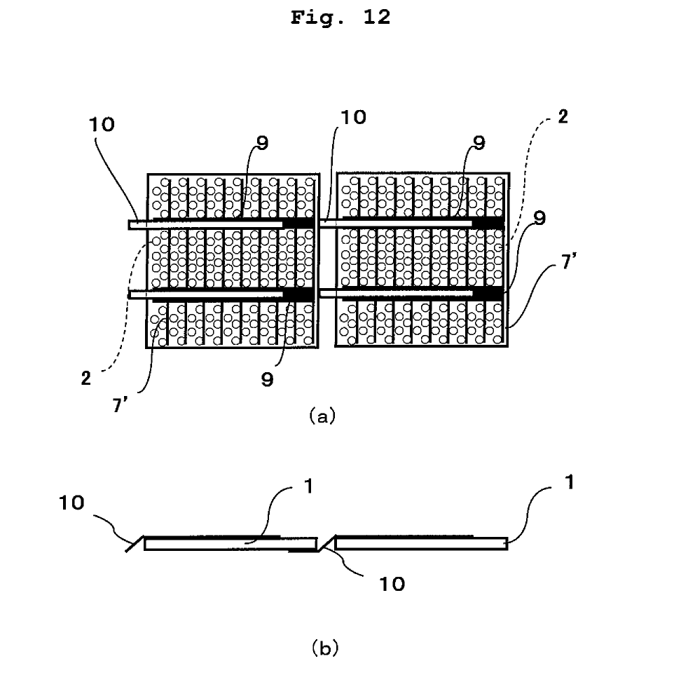

Thus, the photoelectric conversion device of the present invention provides a wide bonding area to improve bond strength, than the method of connecting the bus bar electrode 9 to the conductive string material 10 each being provided in the general photoelectric conversion device of the related art as shown in FIGS. 12(a) and 12(b).

### Third Preferred Embodiment

An example of a third preferred embodiment in the photoelectric conversion device of the present invention will be described in detail with reference to FIGS. 6 to 9.

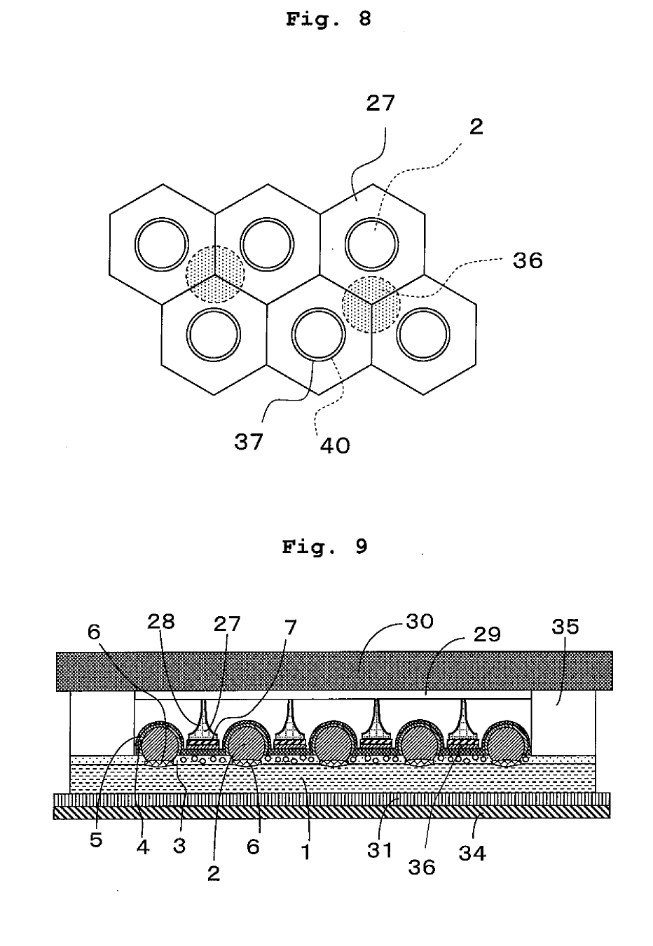

FIG. 6 is a sectional view showing the third preferred embodiment of the photoelectric conversion device of the invention. FIG. 7 is a graph showing the reflectance of an aluminum thin film used as a light reflecting layer of a light reflecting member and the reflectance of solid aluminum, respectively. FIG. 8 is a plan view of the third preferred embodiment. FIG. 9 is a sectional view showing an example of a photoelectric conversion module manufactured by using the photoelectric conversion device of the third preferred embodiment.

In the photoelectric conversion device of the third preferred embodiment, a large number of spherical crystal semiconductor particles 2 of a first conductivity type, each having on the surface layer thereof a semiconductor part 4 of a second conductivity type, are bonded at spaced intervals on a conductive substrate 1. An insulating layer 3 is formed on the conductive substrate 1 extending between the crystal semiconductor particles 2 and 2. A light-transmitting conducting layer 5 is formed on the insulating layer 3 and on the crystal semiconductor particles 2. A conductor plate 7 is bonded onto the light-transmitting conducting layer 5 overlying the insulating layer 3, with a conductive bonding layer 36 in between. A light reflecting member 27 is disposed on the conductor plate 7. The member 27 has a concave mirror-shaped light reflecting surface for collecting light into the crystal semiconductor particles 2, and an aperture 37 for exposing the upper portions of the crystal semiconductor particles 2 is formed at a lower end of the light reflecting surface.

With the above configuration, even if the crystal semiconductor particles 2 account for a small area on the conductive substrate 1, the light can be collected efficiently into the crystal semiconductor particles 2. Hence, the amount of semiconductors used can be reduced while maintaining high photoelectric conversion efficiency, enabling manufacturing of the lightweight and low-cost photoelectric conversion device. Even if the distance between crystal semiconductor particles 2 is increased to not less than 1/10 of the diameter of the crystal semiconductor particle 2, the light incident angle dependence of photoelectric conversion efficiency can be lowered.

Additionally, the solid conductor plate 7 functioning as a collector electrode is more surely bonded onto the light-transmitting conducting layer 5 by the conductive bonding layer 36. This enables current collection properties to be considerably improved than the conventional finger electrodes and the bus bar electrode composed of a conductive paste. Since the collector electrode is not disposed on the crystal semiconductor particles 2, no shadow is formed on the crystal semiconductor particles 2, thereby improving photoelectric conversion efficiency.

When the conductor plate 7 is in contact with the light-transmitting conducting layer 5 without being bonded thereon, the conductor plate 7 might float from the light-transmitting conducting layer 5, making it difficult to make a reliable conductive communication with the light-transmitting conductive layer 5. As a result, current collection properties might be deteriorated. The conductor plate 7 is free from this problem, and ensures a reliable conductive communication with the light-transmitting conductive layer 5. There is also the following problem when the conductor plate 7 is in contact with the light-transmitting conducting layer 5 without being bonded thereon. That is, when a transparent resin or the like is filled so as to cover the crystal semiconductor particles 2 and the light reflecting member 27, the floating transparent resin causes the conductor plate 7 to be dislocated. As a result, the conductor plate 7 might be contacted with the crystal semiconductor particles 2 and might deteriorate photoelectric conversion efficiency. On the other hand, the conductor plate 7 of the invention is free from this problem and capable of increasing the reliability of the photoelectric conversion device.

The conductor plate 7 and the light reflecting member 27 may be integrally constructed in advance by bonding or the like. Alternatively, the conductor plate 7 having on its upper surface the light reflecting member 27 may be bonded onto the light-transmitting conducting layer 5 by the conductive bonding layer 36.

The conductive substrate 1 of the present embodiment may be composed of aluminum, a metal having a melting point higher than the melting point of aluminum, ceramics or the like. For example, the conductive substrate 1 may be composed of aluminum, aluminum alloy, iron, stainless steel, nickel alloy, or alumina ceramics. When the material of the conductive substrate 1 is other than aluminum, a conducting layer composed of aluminum may be formed on the substrate composed of that material.

### <Manufacturing Method>

The photoelectric conversion device of the third preferred embodiment can be manufactured in the same manner as the first preferred embodiment by using the same materials as in the first preferred embodiment.

That is, the formation of the semiconductor layer 4 onto the surface layer of the crystal semiconductor particles 2 may be performed similarly to the first preferred embodiment. This step may be performed before or after the crystal semiconductor particles 2 are bonded onto the conductive substrate 1.

The insulating layer 3 may contain insulating particles 32. Preferably, the insulating particles 32 are composed of an insulating material such as glass, ceramics or resin, and have a mean particle size of 4 to 20 μm. The dispersion of the insulating particles 32 into the insulating layer (the insulating material) 3 ensures that the conducting plate 7 overlaying the insulating layer 3 is kept out of contact with the conductive substrate 1. Subsequently, the paste or the solution or the sheet or the like of the insulating material containing the insulating particles 32 can be used to form the insulating layer 3 in the same manner as the first preferred embodiment.

Similarly to the first preferred embodiment, the light-transmitting conducting layer 5 is formed along the surface of the semiconductor layer 4 or the surfaces of the crystal semiconductor particles 2, and then the conducting plate 7 is formed on the light-transmitting conducting layer 5 with the conductive bonding layer 36 in between. The conducting plate 7 also functions as a support plate for firmly supporting the light reflecting member 27 to be disposed on the conducting plate 7.

The conductive bonding layer 36 is, for example, composed of a thermosetting resin adhesive containing conductive particles, and electrically connects the conducting plate 7 and the light-transmitting conductive layer 5, and also causes these to be mechanically fixed to each other. The conductive particles contained in the conductive bonding layer 36 are preferably composed of at least one of silver, copper, nickel and gold, thereby efficiently collecting the generated current from the light-transmitting conductor layer 5 to the conducting plate 7.

As shown in FIG. 8, the conductive bonding layer 36 also preferably has a circular shape to keep a constant distance from the surrounding crystal semiconductor particles 2. In this case, the resistance between each of the surrounding crystal semiconductor particles 2 and the conductive bonding layer 36 becomes identical, and the non-uniformity of resistance, namely the non-uniformity of current collection properties can be eliminated, so that the current generated in the crystal semiconductor particles 2 can be efficiently collected into the conducting plate 7.

Next, the light reflecting member 27 is disposed on the conducting plate 7. The light reflecting member 27 has a concave mirror-shaped light reflecting surface for collecting light into the crystal semiconductor particles 2, and has, at a lower end of the light reflecting surface, the aperture 37 for exposing the upper portions of the crystal semiconductor particles 2. Specifically, the light reflecting member 27 has the concave mirror shape around the crystal semiconductor particle 2.

Preferably, the light reflecting member 27 has, in the longitudinal section thereof, an acute-angled projection at the peak portion (the boundary portion between the concave mirror-shaped parts). This minimizes the upward reflection of light at the peak portion, so that the incident light can be efficiently reflected to and collected into the crystal semiconductor particles 2. More preferably, the peak portion has an upward-convex curved surface, so that the upward reflection of the light at the peak portion can be further reduced. On the other hand, if the boundary portion between the concave mirror-shaped parts is a wide flat surface, the incident light may be directly reflected upward at the boundary portion, thus deteriorating photoelectric conversion efficiency. The angle of the acute-angled projection is preferably 5° to 60°.

In the light reflecting member 27, the light reflection surface preferably has a partial spheroidal shape. This permits a further reduction of the light incident angle dependence of photoelectric conversion efficiency than that of a partial spherical shape. When the incident angle of light, such as sunlight, is changed with time, the partial spheroidal shape can more efficiently collect lights than the partial spherical shape, based on a computer simulation. Table 1 shows the utilization factor of light when the light reflecting surface of the light reflecting member 27 has the partial spheroidal shape and that in the partial spherical shape, which were obtained in the above computer simulation.

That is, the amount of lights entered into the maximum aperture of the light reflecting member 27 was measured throughout the day by firmly securing and directing the central axis of the concave mirror-shaped part of the light reflecting member 27 to the direction in which the sun crosses the meridian passage. The data in Table 1 indicate the ratio of the lights that could be irradiated to the crystal semiconductor particles 2 with respect to the total amount of the lights.

In Table 1, the case where the concave mirror-shaped part of the light reflecting member 27 is the partial spheroidal shape is specifically the case of a semi-spheroid shape, and the case where the concave mirror-shaped part of the light reflecting member 27 is the partial spherical shape is specifically the case of a semi-spherical shape.

TABLE 1

| | Utilization factor |
|---|---|
| | of incident light |
| Partial spheroidal shape | 97% |
| Partial spherical shape | 94% |

Preferably, the light reflecting member 27 is composed of resin and has on the surface thereof a light reflecting layer 28 composed of metal. The resin constituting the light reflecting member 27 may be, for example, polycarbonate resin, acryl resin, fluororesin or olefin resin. The light reflecting member 27 has, in the lower end thereof, an aperture 37 having such a size as to permit passage of the crystal semiconductor particles 2. The diameter of the aperture 37 is about 1.1 to 1.4 times greater than that of the crystal semiconductor particle 2.

The light reflecting member 27 can be manufactured by molding with press molding method, injection molding method or the like, using a metal mold or the like having a large number of the negative shape of a concave mirror shape (a convex shape). Alternatively, the light reflecting member 27 may be composed entirely of metal and can be manufactured by molding method using a metal mold, cutting method or the like.

The light reflecting layer 28 formed on the concave mirror-shaped surface of the light reflecting member 27 is formed by vacuum deposition method, sputtering method, nonelectrolytic plating method or electrolytic plating method, by using a metal having a high reflectance such as Ag, Al, Au, Cu, Pt, Zn, Ni or Cr. Alternatively, the layer 28 is formed by laminating the foil of the abovementioned metal on the concave mirror-shaped surface of the light reflecting member body composed of the abovementioned resin, and then integrally formed in this state. The light reflecting layer 28 is preferably composed of aluminum (Al). In this case, the light reflecting layer 28 can be formed by an aluminum thin film or aluminum foil, each being inexpensive. Consequently, the light reflecting layer 28 having a high bonding strength with respect to the light reflecting member body composed of the resin can be formed at lost costs.

As shown in FIG. 7, in the visible light range, the aluminum thin film has a higher reflectance than the aluminum bulk (the solid aluminum). Hence, in view of reflectance, lightweight and low-cost, it is preferred that the light reflecting member body is formed by the resin and the aluminum thin film (a thickness of 0.3 to 3 μm) is formed on the light reflecting surface.

Subsequently, the light reflecting member 27 with a large number of the apertures 37, which is formed as a large plate-shaped body, is mounted and bonded onto the conducting plate 7, with the crystal semiconductor particles 2 passed through these apertures 37. Alternatively, instead of bonding, the light reflecting member 27 and the crystal semiconductor particles 2 in this state are covered with transparent filler or a transparent protective material, and then sealed by a vacuum heating apparatus or the like.

In the manufacturing method of Patent Document No. 3 and the like described earlier, the crystal semiconductor particles are inserted one by one into the holes of the aluminum foil. It is however extremely time-consuming task to arrange several thousands to hundreds of thousands of the crystal semiconductor particles. This is not practical as a solar cell required to perform electric generation at low costs. In the present invention, the photoelectric conversion device can be manufactured stably and easily by the batch bonding of the crystal semiconductor particles 2 onto the conductive substrate 1, and the batch manufacturing of the light reflecting member 7 by using the metal mold.

The light reflecting member 27 is preferably composed of an elastically deformable resin. In this case, if there is a concave-convex portion or the like in the conductive substrate 1, the conducting plate 7 or the insulating layer 3, the light reflecting member 27 can be disposed so as to extend along the concave-convex portion. In some cases, the crystal semiconductor particles 2 bonded onto the conductive substrate 1 may be dislocated from the predetermined position. Therefore, if the resin constituting the light reflecting member 27 is hard, the light reflecting member 27 surrounded by the dislocated crystal semiconductor particles 2 may be floated, failing to obtain the desirable light collection characteristics. On the other hand, when the light reflecting member 27 is composed of the elastically deformable resin, the float of the light reflecting member 27 will not propagate to the surroundings, thereby preventing the deterioration of light collection characteristics.

The light reflecting member 27 is composed of an elastically deformable resin and preferably deformed with the force exerted by a finger push, in order to produce the abovementioned effect.

The light reflecting member 27 located in the middle of the conductive substrate 1 is preferably higher than that located in the periphery thereof. In this case, the internal space height (gap) of the photoelectric conversion device can be defined by the light reflecting member 27 located in the periphery of the conductive substrate 1, and it is also possible to prevent deformation of the light reflecting member 27 located in the middle of the conductive substrate 1 and subjected to a large amount of light irradiation. Also in this case, with respect to the height (h1) of the light reflecting member 27 located in the middle of the conductive substrate 1, the height (h2) of the light reflecting member 27 located in the periphery is to be from more than the equivalent value to not more than 4 times (1<h2/h1≦4).

Alternatively, the light reflecting member 27 and the conducting plate 7 are constructed integrally in advance, and bonded onto the light-transmitting conductor layer 5 by the conductive bonding layer 36. This further facilitates manufacturing of the photoelectric conversion device.

Next, a photoelectric conversion module as shown in FIG. 9 is manufactured by using the photoelectric conversion device of the present invention.

A surface-side transparent filler 29 for coating the light reflecting member 27 and the crystal semiconductor particles 2 may be an optically transparent material composed of, for example, ethylene vinyl acetate copolymer (EVA), polyolefin, fluororesin or silicone resin.

A surface protective plate 30 on the surface-side transparent filler 29 is composed of an optically transparent material having weather resistance. The material is composed of glass, silicone resin, fluororesin such as polyvinyl fluoride (PVF), ethylene-tetrafluoroethylene copolymer (ETFE), poly(tetrafluoroethylene) (PTFE), tetrafluoroethylene-perfluoroalkoxy copolymer (PFA), tetrafluoroethylene-hexa-fluoropropylene copolymer (FEP), poly(chlorotrifluoro ethylene) (PCTFE), or the like.

Alternatively, by using the same material as the surface-side transparent filler 29, a back-side filler 31 can be disposed on the back of the conductive substrate 1, and a back protective plate 34 may be laminated thereon. The material of the back protective plate 34 is preferably fluororesin such as polyvinyl fluoride (PVF), ethylene-tetrafluoroethylene copolymer (ETFE) or polychlorotrifluoro ethylene (PCTFE), or a resin such as polyethylene terephthalate (PET). Alternatively, the back protective plate 34 may be a complex resin sheet in which the abovementioned resin sheets are laminated with aluminum foil or a metal oxide film in between, a glass plate, or a metal sheet composed of stainless steel or the like.

A sealing member 35 for defining the internal space vertical gap is disposed at the peripheral part in the internal space of the photoelectric conversion module. The sealing member 35 can be formed easily by forming a frame-shaped groove or a slit for functioning as the sealing member 35 at the peripheral part of the metal mold for forming the light reflecting member 27. The sealing member 35 has the same thickness as the gap between the insulating layer 3 and the surface protective plate 30, and performs the function of ensuring the gap to prevent the light reflecting member 27 from being collapsed when the photoelectric conversion device, the surface-side transparent filler 29 and the surface protective plate 30 are laminated and heated in vacuum.

The sealing member 35 may be formed inside of the internal space of the photoelectric conversion module. When the photoelectric conversion module is large, the central part thereof may be deflected or recessed. Therefore, the deflection and the recess of the photoelectric conversion module can be eliminated by disposing the sealing member 35 inside of the internal space of the photoelectric conversion module. In this case, the sealing member 35 may have the dimension of one semiconductor particle. Alternatively, a large number of the sealing members 35 may be arranged.

The sealing member 35 is composed of a material such as polycarbonate resin, acryl resin, fluororesin or olefin resin.

### Fourth Preferred Embodiment

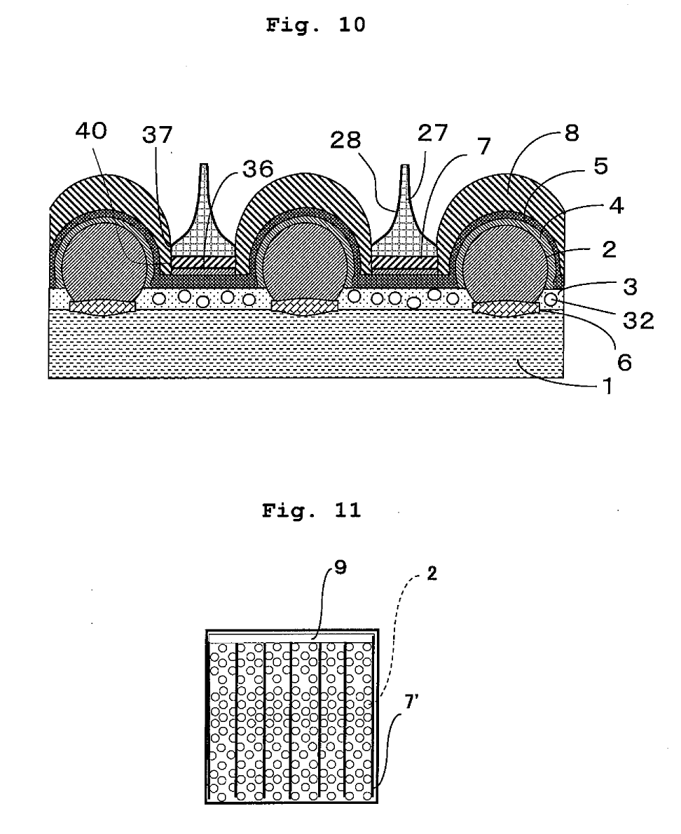

In the photoelectric conversion device of the present invention, as shown in FIG. 10, a light-transmitting light collection layer 8 composed of a lens-shaped member capable of efficiently admitting light may be disposed on crystal semiconductor particles 2 in the photoelectric conversion device manufactured in the third preferred embodiment. The light-transmitting light collection layer 8 is that described in the second preferred embodiment.

With the above configuration, the light reflecting member 27 enables the efficient light collection into the crystal semiconductor particles 2 even if the crystal semiconductor particles 2 accounts for a small area on the conductive substrate 1. Additionally, the light-transmitting light collection layer 8 enables efficient light admission, resulting in effective light collection into the crystal semiconductor particles 2. Hence, the amount of semiconductors used can be reduced while maintaining high photoelectric conversion efficiency, enabling manufacturing of the lightweight and low-cost photoelectric conversion device. Even if the distance between crystal semiconductor particles 2 is increased to not less than 1/10 of the diameter of each crystal semiconductor particle 2, the light incident angle dependence of photoelectric conversion efficiency can be lowered.

The photoelectric conversion device can be obtained by disposing a piece of the photoelectric conversion element of the above configuration (the unit of photoelectric conversion having a crystal semiconductor particle 2), or by connecting a plurality of these (in series, parallel, or series-parallel). Alternatively, a piece of the photoelectric conversion device, or a plurality of the photoelectric conversion devices connected (in series, parallel, or series-parallel), as shown in FIG. 3, may be used as electric generating means, so that the electric power generated is directly supplied from the electric generating means to a direct load. Alternatively, it may be used as an electric generator in which, by power converting means such as an inverter, the electric power generated can be converted to suitable alternating current power and then supplied to an alternating current load such as a commercial power source system or various kinds of electric equipments. It is also possible to use as photoelectric generators such as various types of photovoltaic systems, by placing the above generator on the roof and the wall surfaces of a sunny building.

The photoelectric conversion device of the present invention will be described below in details by way of examples and comparative examples. However, it is to be understood that the present invention is not limited to the following examples.

### Examples 1 to 4

Photoelectric conversion devices having a size of 20×20 mm² were manufactured as follows.

Firstly, silicon particles as p-type crystal semiconductor particles 2 were arranged in a hexagonal packed structure on a conductive substrate 1 composed of an aluminum alloy substrate obtained by the cold rolling of two aluminum alloy layers having sandwiched therebetween a substrate composed of SUS430 (JIS G 4309) with Ni foil mounted on the upper and lower surfaces thereof, respectively. This was heated at 600° C. for 30 minutes to weld these silicon particles onto the aluminum alloy layer, thereby bonding the lower parts of the silicon particles onto the main surface of the conductive substrate 1.

Subsequently, an insulating layer 3 composed mainly of silicone resin was applied thereto so as to expose the upper parts of the silicon particles and to be interposed between the adjacent silicon particles. This was heated in the atmosphere to complete the insulating layer 3. Thereafter, this was cleaned with acid in order to clean the surface of the upper parts of the silicon particles, and a semiconductor layer 4 as a mixed crystal of an n-type crystalline silicon and an amorphous silicon was formed in a thickness of 30 nm on the silicon particles and the insulating layer 3 by plasma CVD method, and an ITO film as a light-transmitting conducting layer 5 was formed and laminated thereon in a thickness of 80 nm by sputtering method.

Subsequently, a conducting plate (a light receiving surface electrode) 7 composed of copper foil having a thickness of 10 μm, which had substantially the same shape as the optically inactive region extending between the crystal semiconductor particles 2 and 2 in the photoelectric conversion device thus manufactured, was disposed thereon with a conductive paste in between. A light-transmitting light collection layer 8 as a resin lens was disposed on the photoelectric conversion device so that the refraction of light can be used to admit light so as to be received while avoiding the optically inactive region extending between the crystal semiconductor particles 2.

The copper foil thickness was changed in the range of 5 to 30 μm, as shown in Table 2 (Examples 1 to 4).

### Comparative Example 1

As a comparative example 1, a photoelectric conversion device was manufactured in the same manner as the above examples, except that, instead of the above copper foil, light receiving surface electrodes 7′ were disposed in lines between the hexagonally-packed crystal semiconductor particles 2 according to Patent Document No. 3 in the related art (FIG. 11). Here, the light receiving surface electrodes 7′ were composed of copper foil of 200 μm wide and 20 μm thick.

### <Evaluation Results>

The electrical characteristics values of Examples 1 to 4 and Comparative Example 1 thus manufactured were measured by irradiating light having a predetermined strength and a predetermined wavelength.

These measurements were made by a solar simulator (WXS155S-10 manufactured by WACOM Electric Co., Ltd.), with the method based on JIS C 8913. The obtained results of the measurements are shown in Table 2.

In Table 2, “η” denotes photoelectric conversion efficiency (%), and FF denotes a curve factor obtained from a short-circuit current I_{sc}, an open voltage V_{OC} and a maximum power Pₘ by the following equation,

FF=Pₘ/(I_{SC}·V_{OC}) [Formula 1]

TABLE 2

| | Cu foil thickness | Current density | Voltage | FF | η |
|---|---|---|---|---|---|
| | (μm) | (mA/cm²) | (V) | (-) | (%) |
| Comparative | 20 | 27.9 | 0.573 | 0.721 | 11.53 |
| Example 1 | | | | | |
| Example 1 | 10 | 28.2 | 0.574 | 0.748 | 12.11 |
| Example 2 | 20 | 28.1 | 0.574 | 0.741 | 11.95 |
| Example 3 | 30 | 28.1 | 0.573 | 0.743 | 11.96 |
| Example 4 | 5 | 28.0 | 0.573 | 0.715 | 11.47 |

Cell size: 20 mm × 20 mm

As can be seen from Table 2, in Example 4 having the copper foil thickness of only 5 μm, the resistance of the copper foil was large and hence the photoelectric conversion efficiency was slightly lower than that of Comparative Example 1. On the other hand, in Examples 1 to 3 having the copper foil thickness of not less than 10 μm, the photoelectric conversion efficiency was improved. From these, it was confirmed that, by disposing the conducting plate (the light receiving surface electrode) 7 composed of the copper foil between the crystal semiconductor particles 2 and 2, and by forming the light-transmitting light collection layer 8 on the crystal semiconductor particles 2, the light receiving surface electrode 7 can be enlarged considerably thereby to reduce resistance loss and improve photoelectric conversion efficiency. It was also found that, by controlling the thickness of the light receiving surface electrode 7 composed of the copper foil to not less than 10 μm, the resistance thereof can be further reduced to permit a further improvement of the photoelectric conversion efficiency.

In Example 4, though the resistance is large because the copper foil thickness is as small as 5 μm, the shadow loss is small and hence achieves the photoelectric conversion efficiency close to that of Comparative Example 1. Additionally, the thin copper foil produces flexibility, and if the light-transmitting conducting layer 5 has unevenness such as a difference of elevation, it can be laminated so as to extend along the unevenness.

### Example 5

A plurality of the cells of photoelectric conversion devices having a size of 100×100 mm² were manufactured, and a planar connection was made as shown in FIGS. 3(a) and 3(b).

Firstly, silicon particles as p-type crystal semiconductor particles 2 were arranged in a lattice on a conductive substrate 1 composed of an aluminum alloy substrate obtained by the cold rolling of two aluminum alloy layers having sandwiched therebetween a substrate composed of SUS430 (JIS G 4309) with Ni foil mounted on the upper and lower surfaces thereof, respectively. This was heated at 600° C. in the atmosphere for 30 minutes to weld these silicon particles onto the aluminum alloy layer, thereby bonding the lower parts of the silicon particles onto the main surface of the conductive substrate 1.

Similarly to Example 1, an insulating layer 3 was formed, and a semiconductor layer 4 as a mixed crystal of an n-type crystalline silicon and an amorphous silicon was formed in a thickness of 30 nm, and an ITO film as a light-transmitting conducting layer 5 was formed. A conducting plate (a light receiving surface electrode) 7 disposed between the crystal semiconductor particles 2 and 2 was mounted on the light-transmitting conducting layer 5 of the photoelectric conversion device thus manufactured. The light receiving surface electrode 7 was provided with copper foil of 10 μm thick having holes so as to be mountable while avoiding the locations of the crystal semiconductor particles 2. A light-transmitting light collection layer 8 as a resin lens was disposed thereon. The copper foil of 10 μm thick had an extension of 10 mm beyond the manufactured photoelectric conversion device so as to make a planer connection with the photoelectric conversion device manufactured in the same method.

### Comparative Example 2

As a comparative example 2, a photoelectric conversion device was manufactured in the same manner as Example 5, except that, instead of the above copper foil, connections were made by the ends of linear members or band-shaped members through a conventional bus bar electrode composed of silver paste (FIGS. 12(a) and 12(b)).

### <Evaluation Results>

The electrical characteristics values of Example 5 and Comparative Example 2 thus manufactured were compared by irradiating light having a predetermined strength and a predetermined wavelength. Further, the tensile strength was measured after making a planar connection of only one cell of the photoelectric conversion device manufactured in the present invention (Example 5), and compared with Comparative Example 2 when the connection was made through the conventional bus bar electrode.

The electric characteristics were measured based on JIS C 8913, as described above. The tensile strength was measured by a tension tester (a spring balance).

TABLE 3

| | Current density | Voltage | FF | η | Electrode strength |
|---|---|---|---|---|---|
| | (mA/cm²) | (V) | (-) | (%) | (kg) |
| Comparative | 27.1 | 0.573 | 0.725 | 11.26 | 0.42 |
| Example 1 | | | | | |
| Example 1 | 28.1 | 0.574 | 0.742 | 11.97 | 1.25 |

Cell size: 100 mm × 100 mm
Average of two pieces

It can be seen from Table 3 that the photoelectric conversion device of the present invention includes no bus bar electrode of the related art, the crystal semiconductor particles 2 can also be disposed in the area occupied by the bus bar electrode, and therefore, shadow loss can be further reduced thereby to increase the optically generated current. It was also confirmed that the planar connection of the photoelectric conversion device increased the area of connection thereby to improve the tensile strength.

### Example 6

A photoelectric conversion module was manufactured as follows. Firstly, by applying phosphorus diffusion processing to p-type crystal silicon particles 2 having a diameter of approximately 300 μm as crystal semiconductor particles 2, a semiconductor part 4 composed of an n+ layer was formed on the surface layer parts of the crystal silicon particles 2, thereby forming a pn junction.

Subsequently, a large number (approximately thirty thousand) of the crystal silicon particles 2 were arranged at spaced intervals (180 μm), which was about 0.6 times greater than the diameter thereof, on the main surface of a conductive substrate 1 composed of aluminum. Then, these crystal silicon particles 2 were bonded onto the conductive substrate 1, while heating for about 10 minutes at a temperature of 577° C. or above, as the eutectic temperature between aluminum and silicon.

The semiconductor part 4 in the vicinity of the bonding portions between the crystal silicon particles 2 and the conductive substrate 1 was then etched away to perform pn isolation. Thereafter, an insulating layer 3 composed of polyimide was formed by filling it between the crystal silicon particles 2 on the conductive substrate 1.

The upper surfaces of the crystal silicon particles 2 were cleaned, and an ITO film as a light-transmitting conducting layer 5 was formed in a thickness of 80 nm.

Subsequently, as shown in FIG. 8, a large number of circular conductive bonding portions 36 composed of an Ag paste (a resin paste containing Ag particles) were applied by screen printing method onto the insulating layer 3 so as to keep a constant distance from the surrounding three crystal silicon particles 2. As a conducting plate 7 being a collector electrode, copper foil of 20 μm thick was used, having on its surface an Ni plated layer and having a large number of through-holes 40 whose diameter was 350 μm slightly larger than the diameter of the crystal silicon particle 2. The conducting plate 7 was bonded by heat-treating at a temperature of 150° C. for 30 minutes, while pressing it onto the insulating layer 3 so that the crystal silicon particles 2 were projected through the through-holes 40 of the conducting plate 7.

Next, a plate-shaped light reflecting member 27 was formed by vacuum molding method using a polycarbonate resin film and a metal mold on which a large number of convex portions having a lengthwise semi-spheroid shape having a maximum width of at least 1.6 times greater than the diameter of the crystal silicon particles 2. The light reflecting member 27 was provided with a large number of concave mirror shapes having apertures 37 having a diameter of 310 μm slightly larger than the diameter of the crystal silicon particles 2. Subsequently, a light reflecting layer 28 composed of Al having a thickness of 1 μm was formed on the concave mirror-shaped surfaces by sputtering method.

The apex part in the longitudinal section of the light reflecting member 27 was a projection having an angle of 10°.

Next, the light reflecting member 27 was mounted on the conducting plate 7 so that the crystal silicon particles 2 were projected through the apertures 37 of the light reflecting member 27. Subsequently, a back filler 31 composed of EVA having a thickness of 0.4 mm, and a back protective plate 34 of a three-layer structure consisting of a PET layer, a SiO₂ layer and a PET layer and having a thickness of 0.1 mm were laminated sequentially on the bottom surface of the conductive substrate 1. Subsequently, a surface transparent filler 29 composed of EVA having a thickness of 0.6 mm, and a surface protective plate 30 composed of ethylene-tetrafluoroethylene copolymer (ETFE) having a thickness of 0.05 mm were laminated sequentially on the crystal silicon particles 2 and the reflecting member 27. This was then laminated by using a vacuum laminator, resulting in the photoelectric conversion module.

### Example 7

A photoelectric conversion module was manufactured in the same manner as Example 6, except that highly reflective aluminum foil having a thickness of 15 μm was used as a reflecting layer 28 of a light reflecting member 27.

### Comparative Example 3

A photoelectric conversion module was manufactured in the same manner as Example 6, except that a large number of crystal silicon particles 2 were closely arranged at spaced intervals of 20 μm on the main surface of the conductive substrate 1, and a finger electrode as a collector was formed on an ITO film as a light-transmitting conducting layer 5 by coating and curing an Ag paste incorporating silver (Ag) particles into a thermosetting resin.

By comparison of the number of the crystal silicon particles 2 used in the foregoing Examples 6 and 7 and Comparative Example 3, it was confirmed that the number of the crystal silicon particles 2 in Comparative Example 3 was 2.42 times greater than that of Example 6 or 7.

The photoelectric conversion efficiency in the photoelectric conversion state (the state before the light reflecting member 27 was mounted) and that in the photoelectric conversion module state (the state after the light reflecting member 27 was mounted) were measured and compared. In Example 6, (Photoelectric conversion efficiency of photoelectric conversion module)/(Photoelectric conversion efficiency of photoelectric conversion element)=2.38. In Example 7, (Photoelectric conversion efficiency of photoelectric conversion module)/(Photoelectric conversion efficiency of photoelectric conversion element)=2.31. Example 6 and 7 had substantially the same photoelectric conversion efficiency as Comparative Example 3, though the number of the crystal silicon particles 2 used therein was 1/2.42 of that of Comparative Example 3.

It is to be understood that the foregoing preferred embodiments are not intended to be limiting of the present invention, but various modifications may be made within the gist of the invention. For example, the following is a modification in the portion of the light receiving surface electrode 7 which extends beyond the conductive substrate 1. That is, from the viewpoint of operability, the shape of the planer connecting portion may be changed to a plurality of strip-shaped connecting portions for imparting flexibility to the tightening between those connected to each other.

1. A photoelectric conversion device comprising a conductive substrate, a plurality of semiconductor elements functioning as a photoelectric conversion element and disposed at spaced intervals on a surface of the conductive substrate, a light-transmitting conducting layer formed on the plurality of the semiconductor elements and on the conductive substrate therebetween, and a collector electrode formed on a surface of the light-transmitting conducting layer, wherein the collector electrode is comprised of a conductor plate provided with a plurality of through-holes to admit external light into each semiconductor element.

2. The photoelectric conversion device according to claim 1, wherein the conductor plate covers an optically inactive portion being inactive against photoelectric conversion between the semiconductor elements.

3. The photoelectric conversion device according to claim 1, wherein
the semiconductor elements are crystal semiconductor particles of a first conductivity type having on a surface layer thereof a semiconductor part of a second conductivity type, and a plurality of the crystal semiconductor particles are bonded at spaced intervals onto the conductive substrate;
an insulating layer is formed on the conductive substrate extending between the crystal semiconductor particles, and the light-transmitting conducting layer is formed on the insulating layer and on the crystal semiconductor particles; and
a light-transmitting light collection layer for collecting light into each of the crystal semiconductor particles is formed on the light-transmitting conducting layer and the collector electrode.

4. The photoelectric conversion device according to claim 3, wherein the light-transmitting light collection layer collects the light into each of the crystal semiconductor particles by light refraction action.

5. The photoelectric conversion device according to claim 3, wherein the light-transmitting light collection layer is formed in a convex curved surface shape above each of the crystal semiconductor particles.

6. The photoelectric conversion device according to claim 1, wherein the conductive substrate is composed of aluminum, and the semiconductor elements are composed of silicon.

7. The photoelectric conversion device according to claim 1, wherein the collector electrode contains at least one selected from the group consisting of gold, platinum, silver, copper, aluminum, tin, iron, nickel, chrome and zinc.

8. The photoelectric conversion device according to claim 7, wherein the collector electrode is composed of copper foil having a thickness of at least 5 μm.

9. The photoelectric conversion device according to claim 3, wherein the light-transmitting light collection layer is in a non-spherical shape, having in a longitudinal section thereof, a contour shape of a substantially semicircular shape having a larger diameter than the crystal semiconductor particles and having a lateral width smaller than a height thereof.

10. The photoelectric conversion device according to claim 9, wherein the light-transmitting light collection layer is in a spherical shape having an apex identical in curvature to the crystal semiconductor particles.

11. The photoelectric conversion device according to claim 10, wherein both sides other than the apex of the contour shape in the longitudinal section are comprised of a circular arc having a larger diameter than the crystal semiconductor particles.

12. The photoelectric conversion device according to claim 11, wherein the diameter of the circular arc is 2 to 2.5 times greater than the diameter of the crystal semiconductor particles.

13. The photoelectric conversion device according to claim 3, wherein the light-transmitting light collection layer is composed of at least one selected from the group consisting of ethylene vinyl acetate resin, fluoroplastic, polyester resin, polypropylene resin, polyimide resin, polycarbonate resin, polyarylate resin, polyphenylene ether resin, silicone resin, polyphenylene sulfide resin and polyolefin resin.

14. The photoelectric conversion device according to claim 1, wherein
the semiconductor elements are crystal semiconductor particles of a first conductivity type having on a surface layer thereof a semiconductor part of a second conductivity type, and a plurality of the crystal semiconductor particles are bonded at spaced intervals onto the conductive substrate;
an insulating layer is formed on the conductive substrate extending between the crystal semiconductor particles; and
a light reflecting member having a light reflecting surface of a concave mirror shape for collecting light into each of the crystal semiconductor particles is formed on the collector electrode.

15. The photoelectric conversion device according to claim 14, wherein
the collector electrode is bonded onto the light-transmitting conducting layer with a conductive bonding layer in between, and
the light reflecting member has a light reflecting surface of a concave mirror shape for collecting light into the crystal semiconductor particles, the light reflecting member having, at a lower end of the light reflecting surface, an aperture for exposing an upper part of each of the crystal semiconductor particles.

16. The photoelectric conversion device according to claim 14, wherein the light reflecting member is composed of resin and having on a surface thereof a light reflecting layer composed of metal.

17. The photoelectric conversion device according to claim 16, wherein the light reflecting layer is composed of aluminum.

18. The photoelectric conversion device according to claim 14, wherein the light reflecting member is composed of an elastically deformable resin.

19. The photoelectric conversion device according to claim 14, wherein in a longitudinal section of the light reflecting member, a peak portion thereof is an acute-angled projection.

20. The photoelectric conversion device according to claim 14, wherein the light reflecting member has the light reflecting surface having a partial spheroidal shape.

21. The photoelectric conversion device according to claim 14, wherein the height of light reflecting member located in the periphery of the conductive substrate is higher than that of located in the center thereof.

22. The photoelectric conversion device according to claim 15, wherein the conductive bonding layer contains, as a conductive particle, at least one selected from the group consisting of silver, copper, nickel and gold.

23. The photoelectric conversion device according to claim 15, wherein the conductive bonding layer is composed of a circular conductive bonding part keeping a constant distance from the crystal semiconductor particles around the conductive bonding layer.

24. The photoelectric conversion device according to claim 1, wherein
the semiconductor elements are crystal semiconductor particles of a first conductivity type having on a surface layer thereof a semiconductor part of a second conductivity type, and a plurality of the crystal semiconductor particles are bonded at spaced intervals onto the conductive substrate;
a light-transmitting light collection layer for collecting light into each of the crystal semiconductor particles is formed on the light-transmitting conducting layer; and
a light reflecting member having a light reflecting surface of a concave mirror shape for collecting light into each of the crystal semiconductor particles is formed on the collector electrode.

25. A photoelectric conversion device in which a plurality of semiconductor elements functioning as a photoelectric conversion element are disposed at spaced intervals on a surface of a conductive substrate, a light-transmitting conducting layer is formed on the plurality of the semiconductor elements and on the conductive substrate therebetween, and a collector electrode is formed on a surface of the light-transmitting conducting layer, wherein the collector electrode is comprised of a conductor plate with through-holes covering the region between the semiconductor elements and corresponding to the semiconductor elements.

26. A complex type photoelectric conversion device in which a plurality of the photoelectric conversion device according to claim 1 are electrically connected to each other through the conductor plate, wherein one edge of the conductor plate of one of the photoelectric conversion devices extends to the adjacent photoelectric conversion device so as to be electrically connected to each other.
